(19) United States
(12) Patent Application Publication
(10) Pub. No.: US 2004/0070438 A1
(43) Pub. Date: Apr. 15, 2004

(54) Limiter

(76) Inventor: Kenichi Ohshima, Tokyo (JP)

Correspondence Address: Kenichi Ohshima, 6-25-2-303, Nishigotanda, Shinagawa-ku, Tokyo, 141-0031, JP

(21) Appl. No.: 10/270,429

(22) Filed: Oct. 15, 2002

(51) Int. Cl. H03L 5/00

(52) U.S. Cl. 327/309

(57) ABSTRACT

This is invention about the limiter which disappearance of low swing signal is a little.

The signal of a part going over amplitude limiting value are all lost in conventional limiter.

In this invention limiter, swing part going over limiting value is lost too, but small level signal of frequency high relatively to exist in the lost part at the same time isn't lost much.

You can design the small noise hearing aid, the small power and big sound audio amplifier, the sound recorder that both parties of the near sound and distant sound are recorded distinctly, the soundproofing apparatus that the small sound is heard normally, the small sidetone telephone, the transmitter that it is possible for communication in transmission medium of low rate, and etc., if use this invention limiter.

### BACKGROUND OF THE INVENTION

Limiter circuit is known to limit dynamic range of audio signal in electronic circuit.

But all signal of level to go over limiting value has been lost in conventional limiter circuit.

Low frequency signal level is bigger than high frequency signal level in sound signal, usually.

And, the wave of various frequency exists simultaneously, in many cases sound.

The conventional limiter has a weak point that low swing signal of high frequency to exist in a high swing part of low frequency signal was lost.

So that, if high level signal is input, actualization of the limiter which disappearance of the low swing signal which is existed in with the high swing signal is a little was a technical problem.

### SUMMARY OF THE INVENTION

This is invention about the limiter which disappearance of existing low swing signal is a little in a high swing signal.

This invention limiter works like next.

When a level of input signal voltage goes up, and output signal turns into upper limit of limiting level, then, the level of output signal voltage is fixed in to upper limiting level, even if the level of input signal changes to more high direction.

And, if the level of input signal voltage turns from high direction to drop direction, the input signal level of drop starting point or that neighborhood forms the output side in as upper limit of limiting level, and, the following dropping signal appears at the output circuit.

And, when a level of input signal voltage goes down, and output signal turns into lower limit of limiting level, then, the level of output signal voltage is fixed in to lower limiting level, even if the level of input signal changes to more low direction.

And, if the level of input signal voltage turns from drop direction to up direction, the input signal level of up starting point or that neighborhood forms the output side in as lower limit of limiting level, and, the following upping signal appears at the output circuit.

As for this limiter working as above, disappearance of a high swing signal and at the same time existing low swing signal are little.

### BRIEF DESCRIPTION OF THE DRAWINGS

FIG. 1 are the drawing of the example of the limiter circuit by this invention, and the wave form chart for the explanation of operation.

FIG. 2 is an drawing of the example view of an output signal wave of the conventional limiter.

FIG. 3 is the drawing of the circuit example that the limiter level design is easy.

FIG. 4 is the drawing of the circuit example that output voltage of signal input side amplifier may be small.

FIG. 5 is the drawing of the circuit example that limiter level is equal with the maximum output voltage of amplifier circuit.

FIG. 6 is the drawing of the circuit example that smooth amplitude limiting waveform signal is output.

Name of each reference number or mark R1-R28 are resistors. C1-C11 are capacitors. Q1 and Q2 are transistors. Q3˜Q5 are electric field effect transistors. D1-D10 are diodes. OP1-OP17 are operational amplifiers. NOR is NOR gate circuit. BUF1˜BUF2 are buffer amplifiers. t1-tl4 are the point on the time-axis. INPUT is the input circuit. OUTPUT is the output circuit. +Vcc and −Vcc are the power supply. GND is the grounded circuit. i1-i2 are emitter currents.

### DETAILED DESCRIPTION OF THE INVENTION

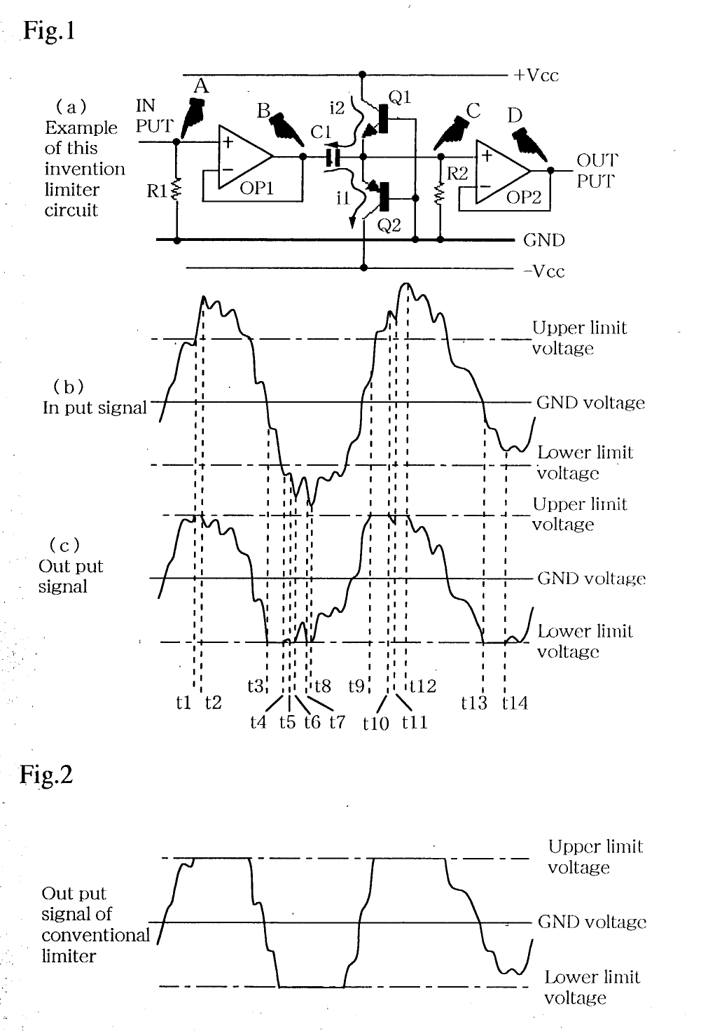

FIG. 1 is explanatory drawing of the example of this invention limiter circuit of operation.

Next are description of FIG. 1.

1) FIG. 1(a) is circuit example drawing of this invention limiter.

2) OP1 is an operational amplifier and the end of R1 is connected to plus input terminal of OP1.

And the other end of R1 is connected to the GND circuit.

3) The output terminal of OP1 is connected to minus input terminal of OP1.

So that output impedance of OP1 is very low.

4) End of C1 is connected to the output terminal of OP1.

And the other end of C1 is connected to the output terminal of OP2.

Accordingly output signal of OP1 passes through C1, and it is input into OP2.

5) End of R2 is connected to plus input of OP2.

And the other end of R2 is connected to GND circuit.

Therefore, in the non-signal state, the potential of the input terminal of OP2 is equal to a GND circuit.

Moreover, R2 is a high impedance enough in normal operation as compared with C1.

6) Input impedance of amplifier by OP2 is high.

7) Q1 is an NPN transistor, an emitter is connected to the plus input circuit of OP1, and the collector is connected to +Vcc, respectively.

8) Q2 is a PNP transistor and an emitter is connected to the plus input circuit of OP1, and the collector is connected to −Vcc, respectively.

9) FIG. 1(b) is drawing of a signal wave form example inputted into the INPUT circuit of FIG. 1(a).

And, FIG. 1(c) is OP2 output-signal wave form chart when the signal wave form of FIG. 1(b) is inputted into the circuit of FIG. 1(a).

10) Three horizontal lines of FIG. 1(b) and FIG. 1(c) show the each next voltage.

Upper side line: upper limit voltage of limiter

middle line: GND voltage

Under side line: lower limit voltage of limiter

The voltage between lines of GND to the upper side line is equal Vbe of Q2, and the voltage between lines of GND to under side line is equal Vbe of Q1.

11) A time-axis advances on from the left to the right, in FIG. 1(b) and FIG. 1(c).

12) The C point voltage of FIG. 1(a) changes same as A point voltage or B point voltage the B point from the left end in the page, when waveform signal of FIG. 1(b) was input into INPUT circuit of FIG. 1(a).

13) The B point voltage of FIG. 1(a) changes same as the A point voltage, time from t1 to t2.

But C point voltage doesn't change.

Because, when GND to C point voltage goes over Q2 Vbe, emitter current i1 flows to Q2.

So that C point voltage is held by upper limit of Limiting voltage.

C1 is charged by i1 at this time.

14) The voltage of input signal turns in a drop from go up at t2. Then the voltage of B point and C point starts a drop together, too.

This continues to t3.

15) The voltage of GND to C point becomes equal as Vbe of Q1 at t3.

So that, emitter current i2 flows to Q1, and C point is held in this voltage, even if the B point voltage becomes less than that voltage.

Therefore, the voltage of C points does not change to t4.

16) The B point voltage starts go up at t4.

So that the C point voltage goes up with B point, too.

But that drops again in a minute, and it is held at t5.

17) The signal done the amplitude limiting that seemed to be FIG. 1(c) of appears at C point, by operation as 13)-17) are repeated.

And the signal wave form of C points is outputted through OP2.

18) FIG. 1(c) is the waveform that amplitude limiting was performed for low frequency and large swing input signal.

And information of low swing signal is lost partly, too.

But difference with input signal is a little.

FIG. 2 is the waveform that the signal of FIG. 1(b) was done amplitude limiting by conventional limiter of limiting value to be equal with the FIG. 1(a) limiter.

All of information to go over amplitude limiting value is lost in conventional limiter, like waveform of FIG. 2.

That is to say, this invention limiter surpasses than conventional limiter, in loss of information.

When amplitude limiting of sound signal is performed strongly with this invention limiter, there is much disappearance of low frequency information.

But high frequency information disappearance is a little.

So that, playback sound of this signal is clear.

And, this characteristic is beneficial for hearing aid very much.

I describe how this limiter is useful for hearing aid next.

There is the next weak point to conventional hearing aid.

1) There is much noise of high frequency to be unpleasant in a sound.

2) The complicated circuit needs to control impulsive sound.

Low frequency sound weakens more than high frequency sound, in propagation.

So that, as for a sound of hearing aid, low frequency should be emphasized, when sound source is distant.

But, low frequency should not be emphasized, when sound source is near.

As for conventional hearing aid, it isn't possible for the co-existing of characteristic of these two.

Therefore frequency characteristic of conventional hearing aid is set up for the sound that is been generally near to.

So that, high frequency sound of distant sound was too big.

And user heard that as noise.

But, the co-existing of two frequency characteristic is possible, if limiter of this invention is used for hearing aid.

The distant sound is very smaller than the near sound, usually.

So that problem is a little, even if you judge the small sound to be distant and the big sound is near. (Sensitivity characteristic may be controlled like that, in case of human ear.)

So you can get both of “the signal of distant sound that low frequency was emphasized” and “the signal of near sound that low frequency isn't emphasized” by one circuit when seem to be next. (Such frequency characteristic is most suitable as hearing aid use.)

1) You make the sound signal that low frequency level was emphasized. (The circuit to make this signal can be built in limiter.)

2) you pass this invention limiter the signal which was made with 1) clause. (Low frequency signal of big level is made small. And, the small signal isn't given affect.)

In addition to above, impulsive sound is eliminated by operation of limiter.

This invention limiter can be utilized with many instruments in addition to hearing aid.

Next is that example.

1) Audio power amplifier. (Puts out the big sound by small power.)

2) Sound recorder. (Clear sound recording is performed, in both of near sound and distant sound.)

3) The soundproofing apparatus that the small sound is heard normally.

4) The small sidetone telephone.

5) The machine that the communication is performed with sound signal. (The communication is possible on low transfer rate.)

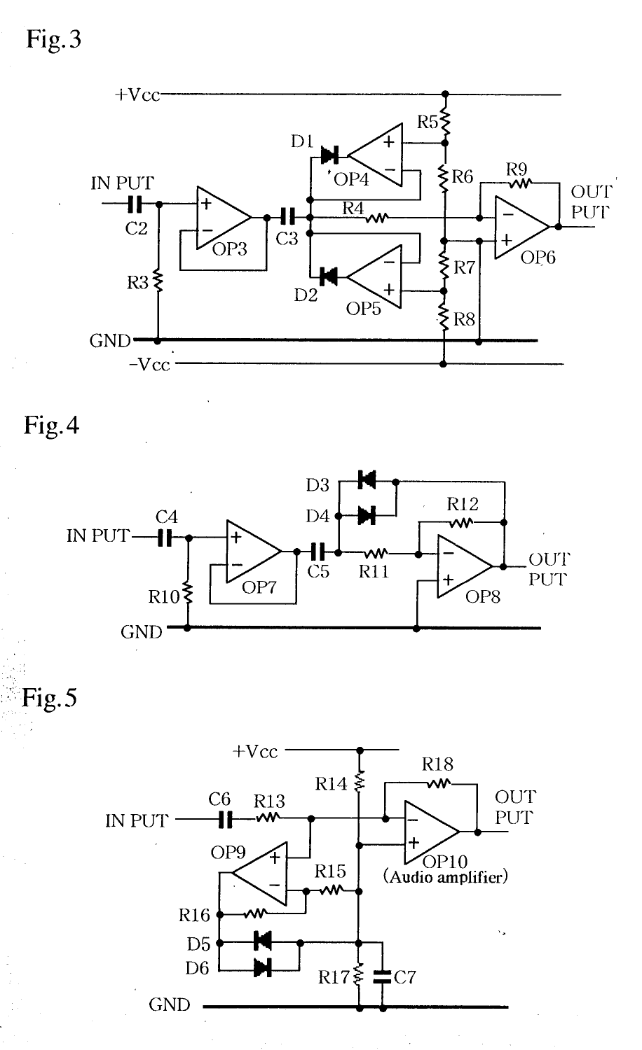

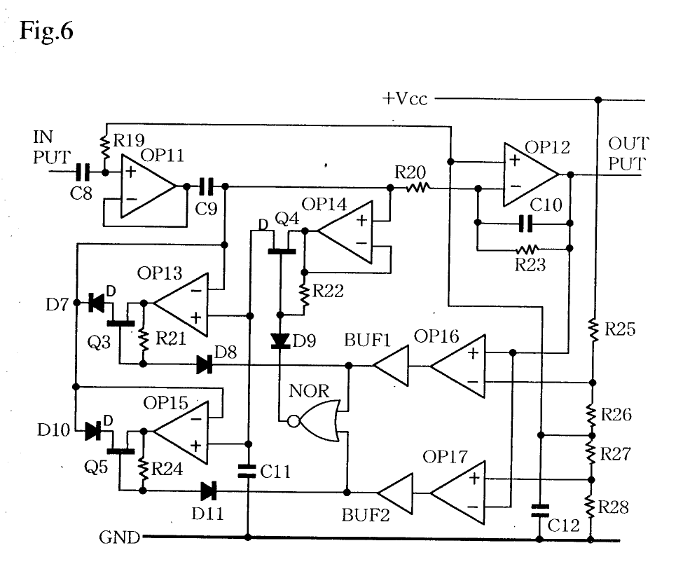

FIG. 3, FIG. 4, FIG. 5, FIG. 6 are variation circuits of FIG. 1(a).

As for FIG. 3 circuit, diodes and operational amplifier is used instead of Q1 and Q2 in FIG. 1.

You can design limiter level in freedom relatively, if this circuit is used.

As for a circuit of FIG. 4, end of D3 and D4 are coupled with output circuit of inversion amplifier OP8.

You can design OP7 to the small output dynamic range, if this circuit is used.

FIG. 5 is the circuit example that amplitude limiting is performed, when bigger than the level that output signal is maximum need is input.

You can design the circuit that amplitude limiting operation is performed with a possible maximum level in that circuit, if this circuit is used.

Addition to above, this circuit is suitable for the audio power amplifier that power supply voltage is easy to fluctuate.

FIG. 6 is the circuit that smooth amplitude limiting waveform signal is output.

As for output circuit (OP12) of this drawing, capacitor was connected to parallel in R12 in the circuit of FIG. 4.

As a result, the signal of smooth waveform is output.

But distortion occurs, if amplitude limiting circuits are equal with FIG. 4.

Because, output signal phase of amplifier consisting of OP12 is more late than input signal.

Therefore, as for the circuit of FIG. 6, amplitude limiting of input signal is to be performed by the input signal voltage when output signal exceeded the detection level.

What is claimed is:

1. The limiter that,
when the electric potential of input signal goes up, and output voltage turns into upper limit or lower limit of limiting level, then, the output voltage is fixed in to upper limiting level or lower limiting level, even if the electric potential of input signal changes to more high direction, and, if the electric potential of input signal turns from up direction to drop direction, the electric potential of input signal drop starting point or that neighborhood forms the output side in as upper limit or lower limit of limiting level,
and, the following signal appears at the output circuit.
And,
when the electric potential of input signal goes drop, and output voltage turns into upper limit or lower limit of limiting level, then, the output voltage is fixed in to upper limiting level or lower limiting level, even if the electric potential of input signal changes to more low direction, and, if the electric potential of input signal turns from drop direction to up direction, the electric potential of input signal up starting point or that neighborhood forms the output side in as upper limit or lower limit of limiting level,
and, the following signal appears at the output circuit.
